(19) United States
(12) Patent Application Publication
(10) Pub. No.: US 2021/0262080 A1
(43) Pub. Date: Aug. 26, 2021

(54) SPUTTER DEVICE

(71) Applicant: Tokyo Electron Limited, Tokyo (JP)

(72) Inventors: Junichi TAKEI, Nirasaki-shi, Yamanashi (JP); Naoki WATANABE, Nirasaki-shi, Yamanashi (JP); Hiroshi SONE, Nirasaki-shi, Yamanashi (JP); Naoyuki SUZUKI, Tokyo (JP)

(21) Appl. No.: 17/253,796

(22) PCT Filed: Jun. 17, 2019
(86) PCT No.: PCT/JP2019/023903

§ 371 Date: Dec. 18, 2020

(30) Foreign Application Priority Data
Jun. 26, 2018 (JP) 2018-120504

(51) Int. Cl. C23C 14/34; H01J 37/34

(52) U.S. Cl. CPC C23C 14/34; H01J 37/3447

(57) ABSTRACT

The sputter device according to one embodiment of the present invention has: a treatment vessel in which a substrate is housed; a slit plate which is disposed above the substrate inside the treatment vessel so as to be located parallel to a surface of the substrate and which has formed therein an opening that penetrates in the plate-thickness direction; and a heat-receiving plate which is formed of a material having a higher heat resistance than the slit plate and which is placed on top of the slit plate beneath a target material provided at a slant with respect the slit plate.

### CROSS-REFERENCE

This is a National Phase Application filed under 35 U.S.C. 371 as a national stage of PCT/JP2019/023903, filed Jun. 17, 2019, an application claiming the benefit of Japanese Application No. 2018-120504, filed Jun. 26, 2018, the content of each of which is hereby incorporated by reference in its entirety.

### TECHNICAL FIELD

The present disclosure relates to a sputter device.

### BACKGROUND

A sputter device is known that radiates sputtered particles to a substrate from a target material arranged to be inclined with respect to the surface of the substrate, and allows the sputtered particles to pass through an opening portion in a slit plate provided between the target material and the substrate so as to form a film on the substrate (see, for example, Patent Document 1).

### PRIOR ART DOCUMENT

### Patent Document

Patent Document 1: Japanese Laid-Open Patent Publication No. 2015-67856

The present disclosure provides a technique capable of suppressing thermal deformation of a slit plate.

### SUMMARY

A sputter device according to an aspect of the present disclosure includes a processing container configured to accommodate a substrate therein; a slit plate in the processing container arranged above the substrate to be parallel with a surface of the substrate, and including an opening portion penetrating the slit plate in a thickness direction of the slit plate; and a heat reception plate placed on the slit plate below a target material provided to be inclined with respect to the slit plate, and formed of a material having higher heat resistance than the slit plate.

According to the present disclosure, it is possible to suppress thermal deformation of the slit plate.

### BRIEF DESCRIPTION OF DRAWINGS

FIG. 1 is a cross-sectional view (1) illustrating an exemplary configuration of a sputter device according to a first embodiment of the present disclosure.

FIG. 2 is an enlarged view illustrating a portion of the sputter device shown in FIG. 1.

FIG. 3 is a cross-sectional view of the sputter device taken along line in FIG. 2.

FIG. 4 is a plan view illustrating an exemplary configuration of a slit plate.

FIG. 5 is a perspective view illustrating an exemplary configuration of the slit plate.

FIG. 6 is an exploded perspective view of the slit plate of FIG. 5.

FIG. 7 is a cross-sectional view of the slit plate taken along line VII-VII in FIG. 5.

FIG. 8 is a perspective view illustrating an exemplary configuration of a heat reception plate.

FIG. 9 is a cross-sectional view (2) illustrating an exemplary configuration of the sputter device according to the first embodiment of the present disclosure.

FIG. 10 is a cross-sectional view (3) illustrating an exemplary configuration of the sputter device according to the first embodiment of the present disclosure.

FIG. 11 is a cross-sectional view illustrating an exemplary configuration of a sputter device according to a second embodiment of the present disclosure.

### DETAILED DESCRIPTION

Hereinafter, non-limiting exemplary embodiments of the present disclosure will be described with reference to the accompanying drawings. In all of the accompanying drawings, the same or corresponding members or components will be denoted by the same or corresponding reference numerals, and redundant explanations will be omitted.

### First Embodiment

### (Sputter Device)

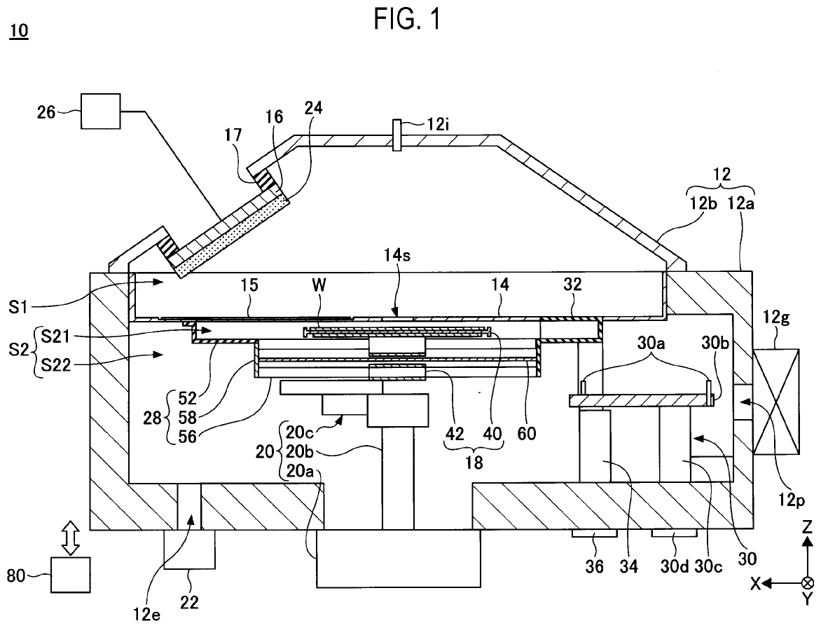

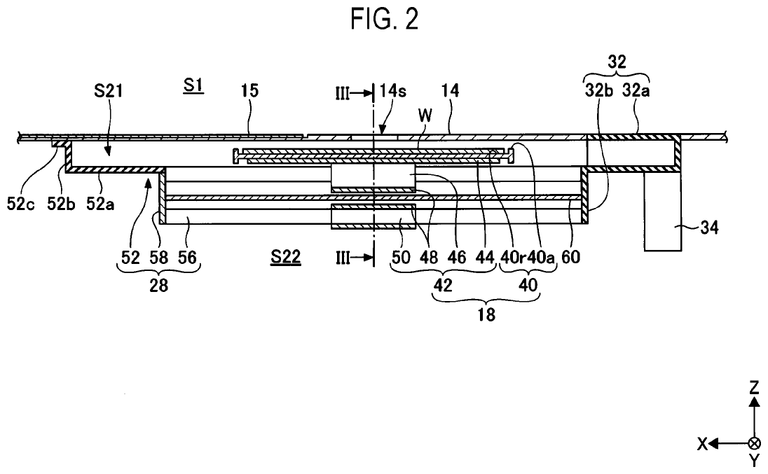

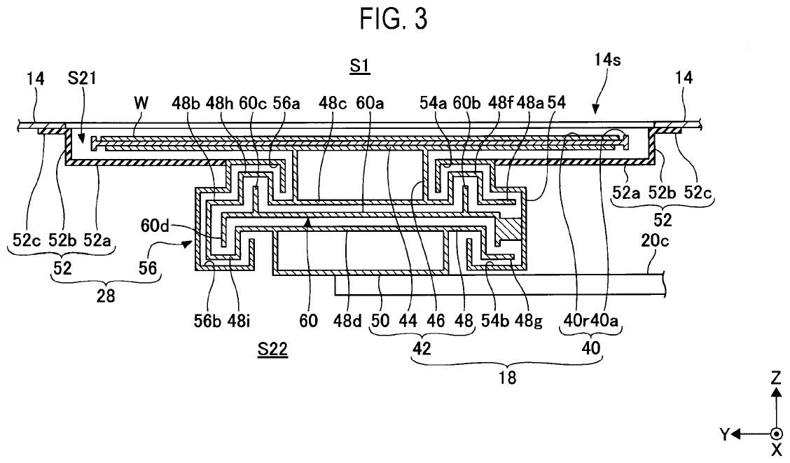

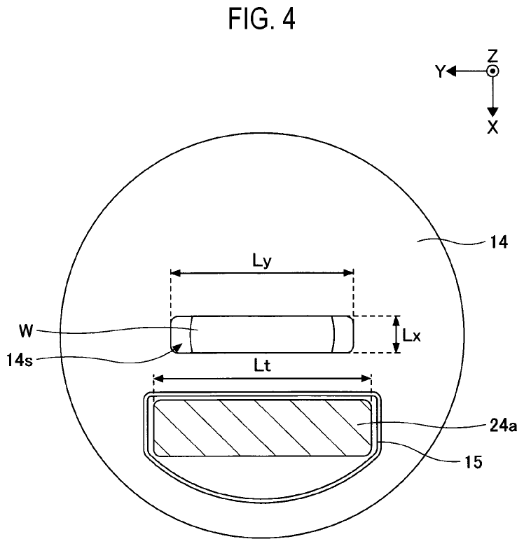

An exemplary configuration of a sputter device according to a first embodiment will be described. FIG. 1 is a cross-sectional view illustrating an exemplary configuration of the sputter device according to the first embodiment of the present disclosure. FIG. 2 is an enlarged view illustrating a portion of the sputter device shown in FIG. 1. FIG. 3 is a cross-sectional view of the sputter device taken along line in FIG. 2. FIG. 4 is a plan view illustrating an exemplary configuration of the slit plate, and illustrates the slit plate when viewed from above.

As shown in FIG. 1, the sputter device 10 includes a processing container 12, a slit plate 14, a heat reception plate 15, a holder 16, a stage 18, a movement mechanism 20, and a controller 80.

The processing container 12 has a main body 12a and a lid 12b. The main body 12a has, for example, a substantially cylindrical shape. The upper end of the main body 12a is open. The lid 12b is installed on the upper end of the main body 12a, and closes the opening at the upper end of the main body 12a.

An exhaust port 12e is formed in the bottom portion of the processing container 12. An exhaust apparatus 22 is connected to the exhaust port 12e. The exhaust apparatus 22 includes, for example, a pressure control device and a decompression pump. The decompression pump may be, for example, a dry pump or a turbo molecular pump.

An opening 12p is formed in the side wall of the processing container 12. A substrate W is loaded into the processing container 12 through the opening 12p, and is unloaded from the processing container 12 through the opening 12p. The opening 12p is opened/closed by the gate valve 12g.

A port 12i for introducing a gas into the processing container 12 is installed in the processing container 12, and a gas (e.g., an inert gas) from a gas supply part is introduced into the processing container 12 through the port 12i.

The slit plate 14 is installed in the processing container 12. The slit plate 14 is a substantially plate-shaped member, and is made of a metal material such as aluminum or stainless steel. The slit plate 14 extends horizontally at an intermediate position in the height direction of the processing container 12. The edge of the slit plate 14 is fixed to the processing container 12. The slit plate 14 divides an interior of the processing container 12 into a first space S1 and a second space S2. The first space S1 is a portion of the space in the processing container 12, and is located above the slit plate 14. The second space S2 is another portion of the space in the processing container 12, and is located below the slit plate 14. An opening portion 14s is formed in the slit plate 14.

The opening portion 14s penetrates the slit plate 14 in the plate thickness direction (the Z direction in the drawing). The slit plate 14 is formed as one component. At the time of film formation in the sputter device 10, the substrate W moves below the opening portion 14s in the X direction, which is a horizontal direction. The opening portion 14s extends in the Y direction, which is another horizontal direction, and has a substantially rectangular shape in a plan view, for example, as shown in FIG. 4. The Y direction is the longitudinal direction of the opening portion 14s and is orthogonal to the X direction. The center of the opening portion 14s in the Y direction substantially coincides with the center of the substrate W in the Y direction at the time of film formation. The width Ly of the opening portion 14s in the Y direction is longer than the width (the maximum width) of the substrate W in the Y direction at the time of film formation, for example, as illustrated in FIG. 4. Meanwhile, the width Lx of the opening portion 14s in the X direction is set to be shorter than the width (the maximum width) of the substrate W in the X direction at the time of film formation. However, the width Lx is not limited thereto, and may be set to be longer than the width of the substrate W in the X direction.

The heat reception plate 15 is placed on the slit plate 14 below a target material 24. The heat reception plate 15 is made of a material having higher heat resistance than the slit plate 14 (e.g., ceramic such as titanium or aluminum oxide). Since the heat reception plate 15 is placed on the slit plate 14 below the target material 24, it is possible to suppress thermal deformation of the slit plate 14 even if the temperature in the vicinity of the target material 24 rises. For example, as illustrated in FIG. 4, the heat reception plate 15 is preferably arranged in a region including an entire projected image 24a obtained by projecting the target material 24 onto the slit plate 14. The top surface of the heat reception plate 15 is substantially flush with, for example, the top surface of the slit plate 14. The detailed structure of the heat reception plate 15 will be described later.

The holder 16 is installed above the slit plate 14. The holder 16 is made of a conductive material. The holder 16 is attached to the lid 12b via an insulating member 17. The holder 16 holds the target material 24 arranged in the first space S1. The holder 16 holds and supports the target material 24 such that the target material 24 is positioned obliquely upwards with respect to the opening portion 14s. In other words, the target material 24 is arranged so as to be inclined with respect to the slit plate 14 in the processing container 12. The target material 24 has, for example, a substantially rectangular shape in a plan view. The width Lt of the projected image 24a obtained by projecting the target material 24 onto the slit plate 14 in the Y direction is larger than the width (the maximum width) of the substrate W in the Y direction at the time of film formation, for example, as illustrated in FIG. 4.

A power supply 26 is connected to the holder 16. The power supply 26 may be a DC power supply when the target material 24 is a metal material. The power supply 26 may be a high frequency power supply when the target material 24 is a dielectric or an insulator, and is electrically connected to the holder 16 via a matcher.

The stage 18 supports the substrate W in the processing container 12. The stage 18 is configured to be movable. At the time of film formation, the stage 18 moves in a movement area S21 along a movement direction (the X direction in FIG. 1). The movement area S21 is an area included in the second space S2, and is an area that includes a space directly below the opening portion 14s and a space directly below the slit plate 14. The stage 18 has one or more convex portions in order to prevent particles from the target material 24 from scattering through the opening portion 14s to an other area S22 in the second space S2 other than the movement area S21. The one or more convex portions of the stage 18 include upwardly and/or downwardly bent portions in a path around the stage 18 between the opening portion 14s and the area S22. That is, the stage 18 forms a path of a labyrinth structure as a path around the stage 18 between the opening portion 14s and the area S22.

The movement area S21 is defined by a wall member 28. The wall member 28 extends along a boundary between the movement area S21 and the area S22. The wall member 28 forms a path between the opening portion 14s and the area S22, together with the stage 18. Due to the wall member 28 and the stage 18, the path between the opening portion 14s and the area S22 becomes a narrow path that is bent, that is, a narrow path of a labyrinth structure.

The stage 18 is installed on the movement mechanism 20. The movement mechanism 20 moves the stage 18. The movement mechanism 20 includes a drive device 20a, a drive shaft 20b, and an articulated arm 20c.

The drive device 20a is installed outside the processing container 12. The drive device 20a is installed on, for example, a bottom portion of the processing container 12. The lower end of the drive shaft 20b is connected to the drive device 20a. The drive shaft 20b penetrates the bottom of the main body 12a from the drive device 20a and extends upwards in the processing container 12. The drive device 20a generates a driving force for moving the drive shaft 20b up and down and rotating the drive shaft 20b. The drive device 20a may be, for example, a motor.

One end of the articulated arm 20c is pivotally supported at the upper end of the drive shaft 20b. The other end of the articulated arm 20c is attached to the stage 18. When the drive shaft 20b is rotated by the drive device 20a, the other end of the articulated arm 20c moves linearly along the X direction. As a result, the movement of the stage 18 in the movement area S21 is carried out. Further, when the drive shaft 20b is moved up and down by the drive device 20a, the articulated arm 20c and the stage 18 are moved up and down.

A substrate lift-up mechanism 30 is installed in an area near the opening 12p in the area S22 of the second space S2. The substrate lift-up mechanism 30 has a plurality of lift pins 30a, a support member 30b, a drive shaft 30c, and a drive device 30d. Each of the plurality of lift pins 30a has a cylindrical shape extending in the vertical direction. The heights of the upper ends of the plurality of lift pins 30a in the vertical direction are substantially the same. The number of lift pins 30a may be, for example, three. The plurality of lift pins 30a is supported by the support member 30b. The support member 30b has a substantially horseshoe-like shape. The plurality of lift pins 30a extends above the support member 30b. The support member 30b is supported by the drive shaft 30c. The drive shaft 30c extends below the support member 30b, and is connected to the drive device 30d. The drive device 30d generates a driving force for moving the plurality of lift pins 30a up and down. The drive device 30d may be, for example, a motor.

The substrate W is transported from the outside of the processing container 12 into the processing container 12 by a transport apparatus (not illustrated). Before the substrate W is placed on the stage 18, the substrate lift-up mechanism 30 receives the substrate W on the upper end of each of the plurality of lift pins 30a. Further, when the substrate W is unloaded to the outside of the processing container 12, the substrate lift-up mechanism 30 receives the substrate W from the stage 18 on the upper end of each of the lift pins 30a. Although a plurality of through holes into which the plurality of lift pins 30a is inserted is formed in the stage 18, the illustration of these through holes is omitted in FIG. 1.

The wall member 28 is opened at one end in the X direction. When the stage 18 moves from the area S22 to the movement area S21, the stage 18 passes through the opening at one end of the wall member 28 in the X direction and enters the movement area S21. When the stage 18 is retracted from the movement area S21 to the area S22, the stage 18 passes through the opening at the one end of the wall member 28 in the X direction.

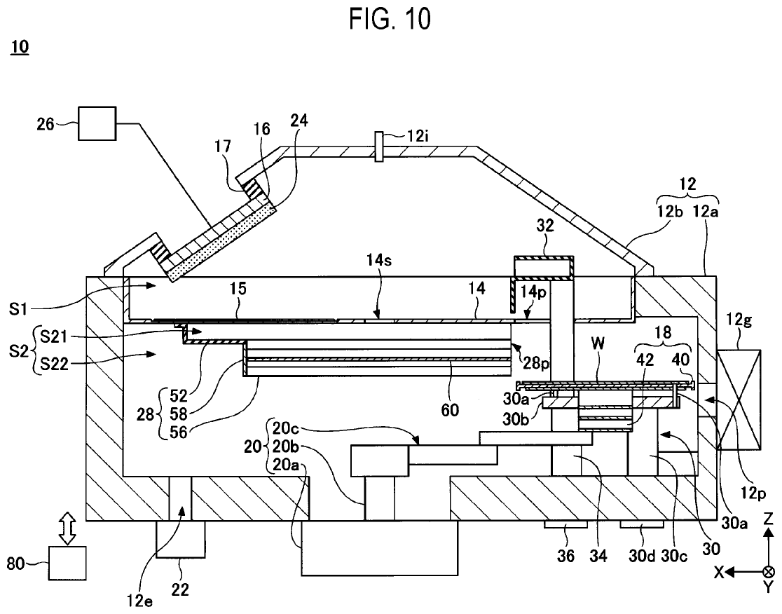

The sputter device 10 includes a lid 32 for opening/closing the opening at one end of the wall member 28. The lid 32 is supported by a drive shaft 34. The drive shaft 34 extends downwards from the lid 32, and is connected to the drive device 36. The drive device 36 generates a driving force for moving the lid 32 up and down. The drive device 36 may be, for example, a motor. As illustrated in FIG. 10 to be described later, the drive device 36 moves the lid 32 upwards to retract the lid 32 from the second space S2 to the first space S1. The slit plate 14 has an opening 14p through which the lid 32 passes when retracted from the second space S2 to the first space S1. When an opening 28p at one end of the wall member 28 is closed, the lid 32 closes the opening 14p in the slit plate 14 at the same time. The components, such as the slit plate 14, the lid 32, and the drive device 36, may be configured such that the lid 32 moves in the Y direction to open/close the opening 28p at one end of the wall member 28 in the X direction. In addition, the components, such as the slit plate 14, the lid 32, and the drive device 36, may even be configured such that the lid 32 moves in the X direction to open/close the opening 28p at the one end of the wall member 28 in the X direction.

The controller 80 controls the operation of each part of the sputter device 10. The controller 80 includes a central processing unit (CPU), a read only memory (ROM), and a random access memory (RAM). The CPU executes desired processing according to a recipe stored in a storage area of, for example, the RAM. In the recipe, apparatus control information for process conditions is set. The control information may include, for example, gas flow rate, pressure, temperature, and process time. A program used by the recipe and the controller 80 may be stored in, for example, a hard disk or a semiconductor memory. For example, the recipe may be provided in a predetermined position to be read in the state of being stored in a storage medium readable by a portable computer, such as a CD-ROM or a DVD.

### (Stage, Wall Member, and Lid)

Details of the stage 18, the wall member 28, and the lid 32 will be described.

The stage 18 has a mounting portion 40 and a support portion 42.

The mounting portion 40 is formed in a substantially plate-like shape extending, for example, in the X direction and the Y direction. The mounting portion 40 has a mounting region 40r on which a substrate W is mounted on the top surface. The mounting portion 40 has a convex portion 40a, which protrudes upwards from the mounting region 40r so as to surround the mounting region 40r.

The support portion 42 is installed below the mounting portion 40. The support portion 42 supports the mounting portion 40. The support portion 42 has an upper portion 44, a connecting portion 46, a hollow portion 48, and a lower portion 50.

The upper portion 44 has a flat plate shape and extends in the X direction and the Y direction. The mounting portion 40 is fixed to the upper portion 44 in the state in which the bottom surface of the mounting portion 40 is in contact with the top surface of the upper portion 44.

The connecting portion 46 extends downward from the bottom surface of the upper portion 44 and is connected to the hollow portion 48. The connecting portion 46 has a pair of flat plate portions. Each of the flat plate portions has a flat plate shape and extends in the X direction and the Z direction. The upper ends of the pair of flat plates of the connecting portion 46 are connected to the bottom surface of the upper portion 44, and the lower ends of the pair of flat plates of the connecting portion 46 are connected to the hollow portion 48.

The hollow portion 48 has a hollow shape. The hollow portion 48 is formed of a plate material that is bent at a plurality of points, and extends along the inner space thereof and the boundary between the space and the outside. When the stage 18 is arranged in the movement area S21, a shielding member 60 to be described later is located in the space inside the hollow portion 48. The hollow portion 48 is opened at opposite ends thereof in the X direction.

The hollow portion 48 has two edge portions 48a and 48b on opposite sides in the Y direction. The two edges 48a and 48b extend in the X direction. The edge 48a forms an opening facing outwards in the Y direction. The opening at the edge 48a is connected to the space inside the hollow portion 48. On the other hand, the edge 48b closes the space inside the hollow portion 48.

The hollow portion 48 has two flat plate portions 48c and 48d. The flat plate portions 48c and 48d are installed between the edge 48a and the edge 48b, and extend in the X direction and the Y direction. The flat plate portions 48c and 48d are substantially parallel to each other. The flat plate portion 48c is separated upwards from the flat plate portion 48d. The lower end of the connecting portion 46 described above is connected to the flat plate portion 48c.

The edge 48a forms convex portions 48f and 48g. The edge 48b forms convex portions 48h and 48i. The convex portions 48f and 48h are provided on opposite sides of the flat plate portion 48c in the Y direction. The convex portions 48f and 48h protrude upwards from the flat plate portion 48c and extend in the X direction. The convex portions 48g and 48i are formed on opposite sides of the flat plate portion 48d in the Y direction. The convex portions 48g and 48i protrude downwards from the flat plate portion 48d and extend in the X direction.

The lower portion 50 is connected to the bottom surface of the flat plate portion 48d, and forms a square tubular shape opened at one end and the other end in the X direction together with the flat plate portion 48d. The other end of the articulated arm 20c of the movement mechanism 20 is connected to the lower portion 50.

The wall member 28 extends along the boundary between the movement area S21 and the area S22, and defines the movement area S21. The wall member 28 has a first member 52, second members 54 and 56, and a third member 58.

The first member 52 defines an area in the movement area S21 in which the mounting portion 40 and the upper portion 44 of the support portion 42 move. The first member 52 is formed of a plate material that is bent at a plurality of locations. The first member 52 includes an opening opened/closed by a portion of the lid 32 at one end thereof in the X direction. The first member 52 has a bottom portion 52a, an intermediate portion 52b, and an upper end portion 52c.

The bottom portion 52a is separated downwards from the slit plate 14, and extends in the X direction and the Y direction. An opening is formed in the bottom portion 52a. When the stage 18 is arranged in the movement area S21, the connecting portion 46 of the support portion 42 of the stage 18 is arranged in the opening formed in the bottom portion 52a. The intermediate portion 52b extends upwards from the edge of the bottom portion 52a, except for the one end side in the X direction. The upper end portion 52c extends in a flange shape from the upper end of the intermediate portion 52b, and is connected to the slit plate 14.

The second member 54 surrounds the edge 48a so as to form a slight gap between the second member 54 and the edge 48a of the hollow portion 48. Specifically, the second member 54 surrounds the convex portions 48f and 48g. The second member 54 is formed of a plate material that is bent at a plurality of locations. The second member 54 includes concave portions 54a and 54b. The convex portion 48f of the stage 18 is inserted into the concave portion 54a. The convex portion 48g of the stage 18 is inserted into the concave portion 54b.

The second member 56 surrounds the edge 48b so as to form a slight gap between the second member 56 and the edge 48b of the hollow portion 48. Specifically, the second member 56 surrounds the convex portions 48h and 48i. The second member 56 is formed of a plate material that is bent at a plurality of locations. The second member 56 includes concave portions 56a and 56b. The convex portion 48h of the stage 18 is inserted into the concave portion 56a. The convex portion 48i of the stage 18 is inserted into the concave portion 56b.

The upper portion of each of the second members 54 and 56 has a flat plate shape extending in the X direction and the Y direction. The upper portion of each of the second members 54 and 56 is arranged in the opening of the bottom portion 52a of the first member 52. The upper portions of each of the second members 54 and 56 is connected to the end surface defining the opening of the bottom portion 52a of the first member 52.

The second members 54 and 56 are spaced apart from each other in the Y direction. When the stage 18 is arranged in the movement area S21, the connecting portion 46 of the support portion 42 of the stage 18 is arranged between the upper portion of the second member 54 and the upper portion of the second member 56. When the stage 18 is arranged in the movement area S21, the lower portion 50 of the support portion 42 of the stage 18 is arranged between the lower portion of the second member 54 and the lower portion of the second member 56.

The second members 54 and 56 are opened at one end and the other end in the X direction. The opening at one end of the second members 54 and 56 in the X direction is a portion of the opening at the one end of the wall member 28 in the X direction. A third member 58 is connected to the other end of the second members 54 and 56 in the X direction so as to close the other end of the movement area S21 in the X direction.

The lid 32 opens and closes the opening at the one end of the wall member 28 in the X direction. The lid 32 has an upper portion 32a and a lower portion 32b. The upper portion 32a is box-shaped. The upper portion 32a forms an opening such that the space inside the lid 32 is connected to the movement area S21 when the lid 32 closes the one end of the movement area S21 in the X direction. The lower portion 32b extends downwards from the end of the upper portion 32a that forms the opening. When the lid 32 closes the one end of the movement area S21 in the X direction, the lower portion 32b closes the opening at the one end of each of the second members 54 and 56 in the X direction and the opening between the one end of the second member 54 in the X direction and the one end of the second member 56 in the X direction. The lower portion 32b of the lid 32 has a flat plate shape extending in the Y direction and the Z direction.

The sputter device 10 further includes a shielding member 60. The shielding member 60 is provided in the movement area S21. When the stage 18 is arranged in the movement area S21, a part of the shielding member 60 is arranged in the space inside the hollow portion 48 of the stage 18.

The shielding member 60 has a flat plate portion 60a and convex portions 60b, 60c, and 60d. The flat plate portion 60a extends substantially parallel to the opening portion 14s. The flat plate portion 60a extends in the X direction and the Y direction. The convex portions 60b and 60c are formed on opposite sides in the Y direction with respect to the flat plate portion 60a, and protrude upwards from the flat plate portion 60a. The convex portion 60d is formed outside the convex portion 60c in the Y direction, and protrudes downwards from the flat plate portion 60a. The convex portions 60b, 60c, and 60d have a flat plate shape extending in the X direction and the Z direction. The shielding member 60 is fixed to the second member 54 at an end portion of the shielding member 60 opposite the convex portion 60d in the X direction. A part of the convex portion 60b is arranged in the space inside the convex portion 48f when the stage 18 is arranged in the movement area S21. A part of the convex portion 60c is arranged in the space inside the convex portion 48h when the stage 18 is arranged in the movement area S21. A part of the convex portion 60d is arranged in the space inside the convex portion 48i when the stage 18 is arranged in the movement area S21.

In the sputter device 10, the path around the stage 18 between the opening portion 14s and the area S22 is bent by the convex portions 48f, 48g, 48h, and 48i installed in the stage 18 so as to form a labyrinth structure. As a result, scattering of particles from the target material 24 into the area S22 is suppressed, and thus unnecessary deposition of the particles from the target material 24 is suppressed. In addition, since the convex portions 48f, 48g, 48h, and 48i are installed in the stage 18, unnecessary scattering and unnecessary deposition of particles from the target material 24 are suppressed without increasing the number of components.

The sputter device 10 has the above-mentioned wall member 28. The width of the path between the opening portion 14s and the area S22 is further narrowed by the wall member 28, and thus scattering of the particles from the target material 24 into the area S22 is further suppressed. In addition, the sputter device 10 includes the shielding member 60. The shielding member 60 further suppresses the scattering of particles from the target material 24 into the area S22. Furthermore, even when film formation processing is performed in the state in which the stage 18 is not arranged in the movement area S21, the shielding member 60 suppresses scattering of the particles from the target material 24 into the area S22.

### (Slit Plate and Heat Reception Plate)

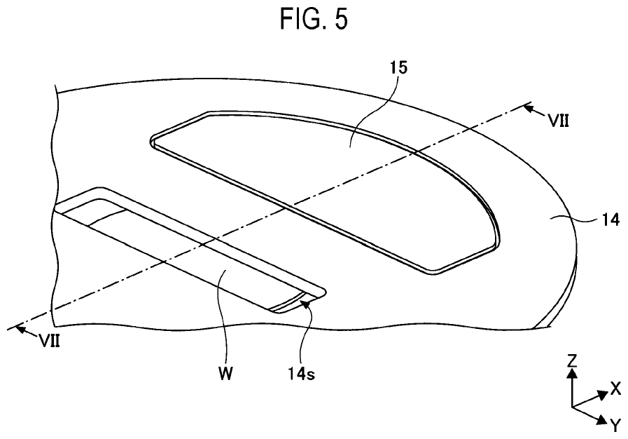

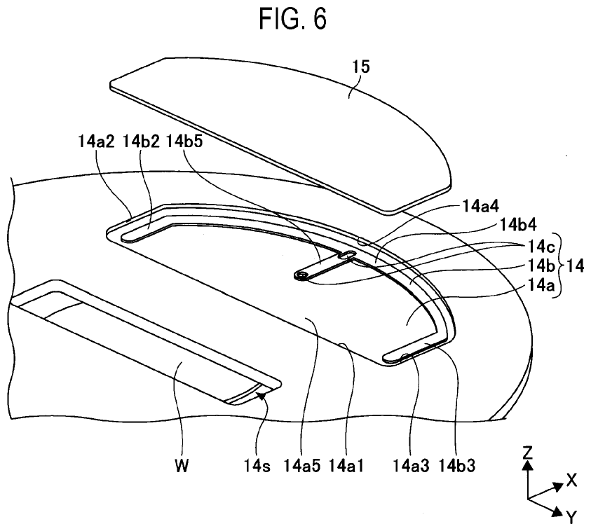

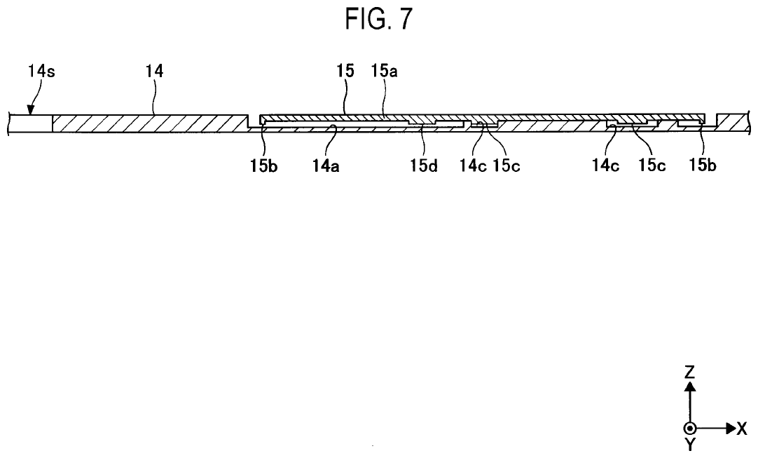

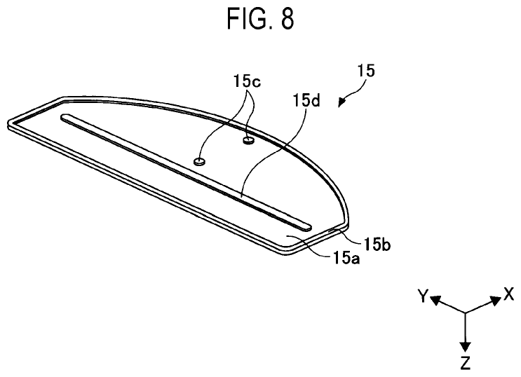

Details of the slit plate 14 and the heat reception plate 15 will be described. FIG. 5 is a perspective view illustrating an exemplary configuration of the slit plate. FIG. 6 is an exploded perspective view of the slit plate of FIG. 5 in the state in which the heat reception plate is removed from the slit plate. FIG. 7 is a cross-sectional view of the slit plate taken along line VII-VII in FIG. 5. FIG. 8 is a perspective view illustrating an exemplary configuration of the heat reception plate when the heat reception plate is viewed from the side on which the heat reception plate is placed on the slit plate.

The slit plate 14 has a concave portion 14a, a support portion 14b, and positioning portions 14c.

The concave portion 14a is formed below the target material 24. A heat reception plate 15 is placed in the concave portion 14a. The concave portion 14a is preferably formed in a region including the entire projected image 24a obtained by projecting the target material 24 onto the slit plate 14. In the example of FIG. 6, the concave portion 14a is formed by a first side wall 14a1, a second side wall 14a2, a third side wall 14a3, a fourth side wall 14a4, and a bottom portion 14a5. The first side wall 14a1 is formed parallel to the opening portion 14s. The second side wall 14a2 is formed so as to extend from one end of the first side wall 14a1 in a direction orthogonal to the first side wall 14a1. The third side wall 14a3 is formed so as to extend from the other end of the first side wall 14a1 in the direction orthogonal to the first side wall 14a1. The fourth side wall 14a4 is formed so as to extend from the second side wall 14a2 towards the third side wall 14a3 in an arc shape. The bottom portion 14a5 is a portion surrounded by the first side wall 14a1, the second side wall 14a2, the third side wall 14a3, and the fourth side wall 14a4.

The support portion 14b is a portion that protrudes upwards from the bottom surface of the concave portion 14a. The protruding height of the support portion 14b from the bottom surface of the concave portion 14a is lower than the height of the concave portion 14a. The support portion 14b is formed at a position far from the opening portion 14s. In the example of FIG. 6, the support portion 14b is formed in a substantially E shape in a plan view. Specifically, the support portion 14b has support portions 14b2, 14b3 and 14b4 formed along the second side wall 14a2, the third side wall 14a3, and the fourth side wall 14a4, respectively. The distance between the support portion 14b2 and the support portion 14b3 may be larger than the opening width Ly of the opening portion 14s. Further, the support portion 14b has a support portion 14b5 that is formed parallel with the support portion 14b2 and the support portion 14b3, between the support portion 14b2 and the support portion 14b3.

The positioning portions 14c are formed in a portion of the support portion 14b. The positioning portions 14c are recesses formed in the support portion 14b, and engage with the positioning portion 15c of the heat reception plate 15 to be described later. As a result, the position of the heat reception plate 15 with respect to the slit plate 14 is determined. The shape of the positioning portions 14c in a plan view may be, for example, a circle, an elongated hole, or a rectangle. In the example of FIG. 6, the case where the number of the positioning portions 14c is two is illustrated, but the number of the positioning portions 14c may be one or may be three or more.

The heat reception plate 15 has a main body 15a, a convex portion 15b, positioning portions 15c, and a reinforcement portion 15d. The main body 15a, the convex portion 15b, the positioning portions 15c, and the reinforcement portion 15d are formed of a material having higher heat resistance than the slit plate 14 (e.g., ceramics such as titanium and aluminum oxide). The main body 15a, the convex portion 15b, the positioning portions 15c, and the reinforcement portion 15d may be formed by integral molding, or may be formed by bonding the above-mentioned portions formed as separate bodies.

The main body 15a has a size slightly smaller than the concave portion 14a in the slit plate 14 in a plan view. The main body 15a is placed on the support portion 14b of the slit plate 14. As a result, the heat reception plate 15 is supported by the support portion 14b by being spaced apart from the bottom surface of the concave portion 14a.

The convex portion 15b is a portion that protrudes downwards from the bottom surface of the main body 15a. When the heat reception plate 15 is placed on the slit plate 14, the convex portion 15b forms a labyrinth structure between the convex portion 15b and the concave portion 14a in the slit plate 14. As a result, it is possible to hinder the particles that may be generated by rubbing on the contact surface between the slit plate 14 and the heat reception plate 15 from being released from the space formed by the top surface of the slit plate 14 and the bottom surface of the heat reception plate 15. In addition, it is possible to hinder the particles released from the target material 24 from entering the space formed by the top surface of the slit plate 14 and the bottom surface of the heat reception plate 15. The convex portion 15b is preferably formed over the entire circumference of the outer peripheral portion of the main body 15a, and the support portion 14b is preferably arranged so as to be the inside of the convex portion 15b.

The positioning portions 15c are formed at positions corresponding to the positioning portions 14c on the slit plate 14. The positioning portions 15c are convex portions protruding downwards from the bottom surface of the main body 15a, and engage with the positioning portions 14c on the slit plate 14. As a result, the heat reception plate 15 is positioned with respect to the slit plate 14. The shape of the positioning portions 15c in a plan view is determined according to the shape of the positioning portions 14c. In the example of FIG. 8, the case where the positioning portions 15c have a cylindrical shape is illustrated.

The reinforcement portion 15d is a portion that protrudes downwards from the bottom surface of the main body 15a. Since the reinforcement portion 15d is formed on the main body 15a, the strength of the heat reception plate 15 is increased. The reinforcement portion 15d has a height that does not come into contact with the bottom surface of the concave portion 14a, for example, when the heat reception plate 15 is placed on the slit plate 14. As a result, since the reinforcement portion 15d does not come into contact with the bottom surface of the concave portion 14a, even if the slit plate 14 or the heat reception plate 15 is deformed due to thermal expansion or contraction, it is possible to prevent generation of particles due to rubbing on the contact surfaces of the reinforcement portion 15d and the concave portion 14a. In the example of FIG. 8, the reinforcement portion 15d is formed so as to extend in the longitudinal direction of the opening portion 14s.

### (Operation of Sputter Device)

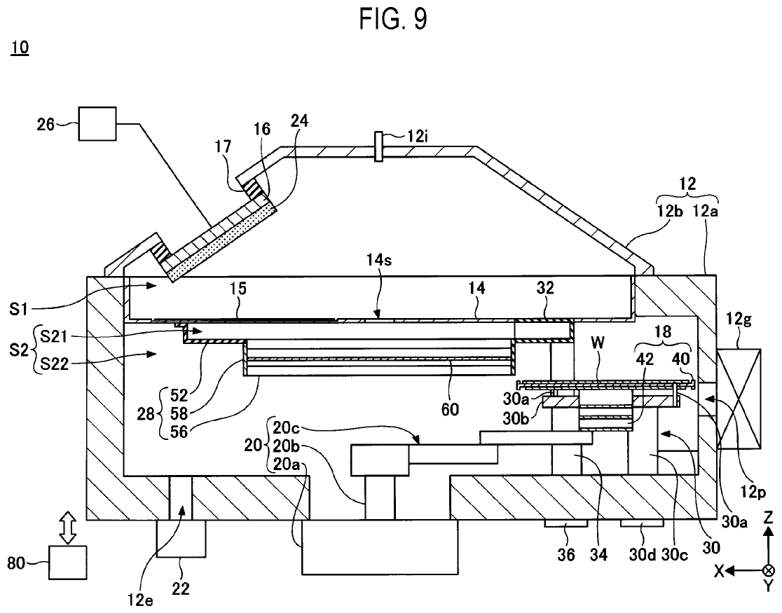

The operation of the sputter device 10 will be described with reference to FIGS. 1, 9, and 10. FIG. 9 is a cross-sectional view illustrating an exemplary configuration of the sputter device 10 of the first embodiment in the state in which a substrate W is mounted on the stage 18. FIG. 10 is a cross-sectional view illustrating an exemplary configuration of the sputter device 10 of the first embodiment in the state in which the lid 32 is moved upwards in order to dispose the substrate W in the movement area S21. The operation of the sputter device 10 illustrated below is executed when the controller 80 controls each part of the sputter device 10.

First, the opening 12p is opened by opening the gate valve 12g. Subsequently, the substrate W is loaded into the processing container 12 by the transport apparatus of the transfer module connected to the sputter device 10. When the substrate W is loaded, the plurality of lift pins 30a and the stage 18 are retracted below the region into which the substrate W is loaded such that the lift pins 30a and the stage 18 do not interfere with the substrate W.

Next, the plurality of lift pins 30a is moved upwards to receive the substrate W from the transport apparatus of the transport module. At this time, the substrate W is supported on the upper ends of the lift pins 30a. After the substrate W is supported by the plurality of lift pins 30a, the transport apparatus of the transport module is retracted from the interior of the processing container 12 to the outside of the processing container 12. Subsequently, the opening 12p is closed by closing the gate valve 12g.

Next, as illustrated in FIG. 9, by moving the stage 18 upwards, the substrate W is delivered from the plurality of lift pins 30a to the stage 18. Subsequently, as illustrated in FIG. 10, the lid 32 is moved upwards such that the lid 32 is retracted into the first space S1. Subsequently, the stage 18 is moved into the movement area S21, and the opening 28p at the one end of the wall member 28 is closed by the lid 32.

Next, gas is introduced into the processing container 12 from the port 12i, and the pressure inside the processing container 12 is set to a predetermined pressure by the exhaust apparatus 22. A voltage is applied to the holder 16 by the power supply 26. When the voltage is applied to the holder 16, the gas in the processing container 12 dissociates and the ions collide with the target material 24. When the ions collide with the target material 24, particles of the constituent material of the target material 24 are released from the target material 24. The particles released from the target material 24 pass through the opening portion 14s, and are deposited on the substrate W. At this time, the substrate W is moved in the X direction. As a result, a film of the constituent material of the target material 24 is formed on the surface of the substrate W.

As described above, the sputter device 10 of the first embodiment includes the slit plate 14, which is arranged above the substrate W in the processing container 12 to be parallel with the surface of the substrate W and has an opening portion 14s penetrating the slit plate 14 in the plate thickness direction. Further, the sputter device 10 has the heat reception plate 15, which is placed on the slit plate 14 below the target material 24 and is made of a material having higher heat resistance than the slit plate 14. As a result, it is possible to suppress the slit plate 14 from being thermally deformed even if the temperature in the vicinity of the target material 24 rises. As a result, since it is possible to bring the position of the target material 24 closer to the substrate W, a high film formation rate is obtained.

In the structure in which the sputtered particles are released from the target material 24, which is arranged to be inclined with respect to the surface of the substrate W, to the substrate W, there is a place at which the target material 24 and a component around the substrate are extremely close to each other. Therefore, a high-temperature region having a high temperature is locally generated in surface of a component around the substrate, particularly, the slit plate 14, which may cause the slit plate 14 to be deformed or damaged and may make it difficult to form a desired film. However, in the sputter device 10, since the heat reception plate 15 formed of a material having higher heat resistance than the slit plate 14 is arranged below the target material 24, it is possible to suppress deformation of or damage to the slit plate 14.

According to the sputter device 10 of the first embodiment, the heat reception plate 15 has the convex portion 15b that forms a labyrinth structure between the bottom surface of the heat reception plate 15 and the top surface of the slit plate 14. As a result, it is possible to hinder the particles that may be generated by rubbing on the contact surface between the slit plate 14 and the heat reception plate 15 from being released from the space formed by the top surface of the slit plate 14 and the bottom surface of the heat reception plate 15. In addition, it is possible to suppress the particles released from the target material 24 from entering the space formed by the top surface of the slit plate 14 and the bottom surface of the heat reception plate 15.

### Second Embodiment

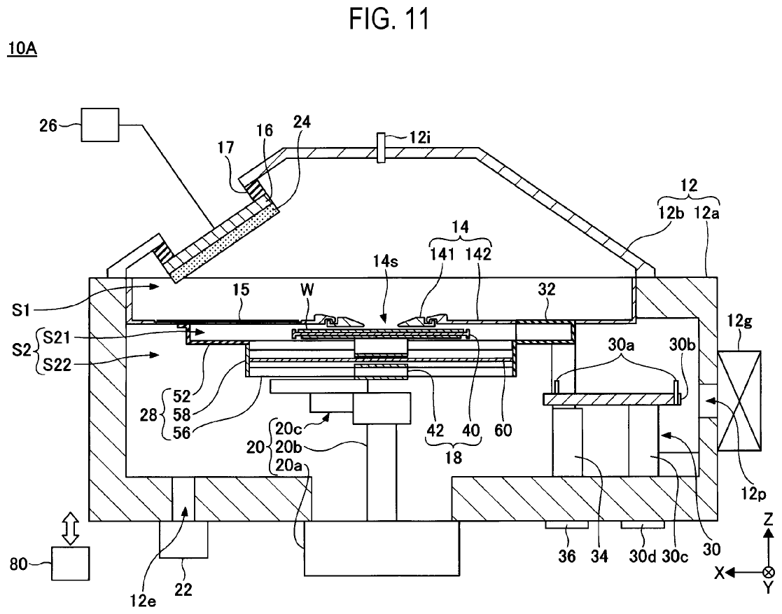

An exemplary configuration of a sputter device according to a second embodiment will be described. FIG. 11 is a cross-sectional view illustrating the exemplary configuration of the sputter device according to the second embodiment of the present disclosure.

As illustrated in FIG. 11, in the sputter device 10A of the second embodiment, the slit plate 14 is formed by combining a plurality of members (an inner member 141 and an outer member 142), which are manufactured as separate bodies, and the inner member 141 is removable from the outer member 142. This makes it possible to change the shape of the opening portion 14s by replacing only the inner member 141 which is a portion of the slit plate 14. Therefore, the shape of the opening portion can be easily changed. Other points are the same as those in the first embodiment.

With the sputter device 10A of the second embodiment, the same effects as those of the first embodiment 10 is obtained.

It should be understood that the embodiments disclosed herein are illustrative and are not limiting in all aspects. The above-described embodiments may be omitted, replaced, or modified in various forms without departing from the scope and spirit of the appended claims.

In the embodiments described above, as a method of moving the substrate W in the processing container 12, the case where the stage 18 is moved by the movement mechanism 20 having the articulated arm 20c has been described, but the present disclosure is not limited thereto. For example, the substrate W may be moved in the processing container 12 by the transport apparatus of the transfer module connected to the sputter device 10.

The present international application claims priority based on Japanese Patent Application No. 2018-120504 filed on Jun. 26, 2018, the disclosure of which is incorporated herein in its entirety by reference.

### EXPLANATION OF REFERENCE NUMERALS

10: sputter device, 12: processing container, 14: slit plate, 14b: support portion, 14s: opening portion, 15: heat reception plate, 15b: convex portion, 16: holder, 24: target material, 24a: projected image, W: substrate

What is claimed is:

1. A sputter device comprising:
a processing container configured to accommodate a substrate therein;
a slit plate arranged in the processing container above the substrate to be parallel with a surface of the substrate, and including an opening portion penetrating the slit plate in a thickness direction of the slit plate; and
a heat reception plate placed on the slit plate below a target material provided to be inclined with respect to the slit plate, and formed of a material having higher heat resistance than the slit plate.

2. The sputter device of claim 1, wherein the heat reception plate is arranged in a region including an entire projected image obtained by projecting the target material onto the slit plate.

3. The sputter device of claim 1, wherein the heat reception plate has a convex portion that forms a labyrinth structure between a bottom surface of the heat reception plate and a top surface of the slit plate.

4. The sputter device of claim 3, wherein the convex portion is formed over an entire circumference of an outer peripheral portion of the heat reception plate.

5. The sputter device of claim 1, wherein the slit plate has a support portion protruding upwards, and
the heat reception plate is supported to be spaced apart from a top surface of the slit plate by the support portion.

6. The sputter device of claim 1, wherein a top surface of the heat reception plate is substantially flush with a top surface of the slit plate.

7. The sputter device of claim 1, wherein the slit plate is formed of aluminum and the heat reception plate is formed of titanium or ceramic.
